(19) United States
(12) Patent Application Publication
(10) Pub. No.: US 2026/0154226 A1
(43) Pub. Date: Jun. 4, 2026

(54) CHIPLET INTEGRATED CIRCUIT (IC) HAVING ACTIVE AND INACTIVE INTERFACE CIRCUITRY

(71) Applicant: Arm Limited, Cambridge (GB)

(72) Inventors: Deepak Goel, San Jose, CA (US); Anitha Kona, Austin, TX (US); Jamshed Jalal, Austin, TX (US); Roma Rudra, Bangalore (IN); Jeffrey Carl Defilippi, Austin, TX (US)

(21) Appl. No.: 18/967,390

(22) Filed: Dec. 3, 2024

(51) Int. Cl. G06F 13/40; H01L 25/07; H03K 17/56

(52) U.S. Cl. CPC G06F 13/4068; G06F 13/4004; H03K 17/56; H10W 90/00; G06F 2213/40

(57) ABSTRACT

Briefly, example apparatuses, articles of manufacture, and/or techniques are disclosed that may be implemented, in whole or in part, to implement, facilitate and/or support integrated circuitry comprising a chiplet having semiconductor circuitry corresponding to an active interface and an inactive interface, where the chiplet may further include contacts connected to the active interface circuitry.

### FIELD

The present disclosure relates generally to integrated circuitry, and more particularly, chiplet-based integrated circuitry.

### BACKGROUND

In a chiplet-based integrated circuit (IC) multiple individual IC dies (chiplets) may be packaged together to form a unified IC device, which may be known as a “multi-chip module,” “hybrid IC,” “2.5D IC,” “advanced package,” “system-level package,” “system-in-package,” and/or the like. Chiplet technology may provide aspects such as ability to mix-and-match different chiplets in different devices, support for heterogeneous integration (e.g., use of chiplet dies having different pitches, sizes, materials, processes, etc. . . . ).

### BRIEF DESCRIPTION OF THE FIGURES

Claimed subject matter is particularly pointed out and distinctly claimed in the concluding portion of the specification. However, both as to organization and/or method of operation, together with objects, features, and/or advantages thereof, it may best be understood by reference to the following detailed description if read with the accompanying drawings in which:

FIGS. 1A-1C illustrate example chiplets, in accordance with an implementation;

FIGS. 2A, 2B illustrate an example chiplet package comprising a plurality of devices, in accordance with an implementation;

FIG. 3 illustrates an example device including a package comprising a plurality of chiplets in accordance with an implementation;

FIG. 4 illustrates an example device comprising instances of chiplets as different versions of a common chiplet design, in accordance with an implementation;

FIG. 5 illustrates an example method of operation, in accordance with an implementation; and

FIG. 6 illustrates an example non-transitory computer-readable medium containing code for fabricating an apparatus, in accordance with an implementation.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others, one or more aspects, properties, etc. may be omitted, such as for ease of discussion, or the like. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. Therefore, the following detailed description is not to be taken to limit claimed subject matter and/or equivalents.

### DETAILED DESCRIPTION

References throughout this specification to one implementation, an implementation, one embodiment, an embodiment, and/or the like means that a particular feature, structure, characteristic, and/or the like described in relation to a particular example, implementation and/or embodiment is included in at least one example, implementation and/or embodiment of claimed subject matter. Thus, appearances of such phrases, for example, in various places throughout this specification are not necessarily intended to refer to the same implementation and/or embodiment and/or to any one particular implementation and/or embodiment. Furthermore, it is to be understood that particular features, structures, characteristics, and/or the like described are capable of being combined in various ways in one or more implementations and/or embodiments and, therefore, are within intended claim scope. Unless explicitly indicated to the contrary, reference to “another example” and/or “a further example” does not indicate that the described example is an exclusive alternative to a preceding example. In general, such examples may be alternatives to and/or additions to previous examples.

As used herein, the term “chiplet” may refer to one of a plurality of integrated circuits disposed within a common package. Chiplets may implement any type of circuitry, such as processing cores, arithmetic processing units, graphics processing units, application specific ICs (ASICs) such as accelerator cores, analog processing circuitry, analog-to-digital / digital-to-analog converters, networking circuitry, memory circuitry, and/or the like. As a simple example, a chiplet-based processor might comprise a number of chiplets that each implement a plurality of processing cores, a chiplet to implement a memory controller, and a chiplet-to-chiplet interconnect to provide the processing chiplets access to the memory chiplet. A chiplet may comprise circuitry to execute operational code, such as boot code as described below. In some cases, separate chiplets may be disposed on separate semiconductor dies. Chiplets may be connected within their package via a chiplet-to-chiplet interconnect. In some cases, such a chiplet-to-chiplet interconnect may be contained entirely within the chiplet package (e.g., lacking package contacts). Packages may expose and/or otherwise provide contacts for power and/or package-external signaling. Chiplets may have unique identities and/or operational roles within their package. For example, chiplets may have separate identifiers used for chiplet-to-chiplet communications. In some cases, a package of chiplets may appear as a single device with respect to devices external to the package. In other cases, a chiplet package may appear as separate devices corresponding to groups of one or more chiplets.

In some implementations, chiplets sharing at least a portion of their design may be include in different chiplet packages. For instance, an instance of a video decoder chiplet might be included in a central processing unit (CPU) package along with processing core chiplets, input/output (I/O) chiplets, and the like, while another instance of the video decoder chiplet might be included in a graphics processing unit (GPU). As another example, a chiplet may be designed to be included in a high-performance-computing (HPC) CPU and a standard or low-power CPU. However, different chiplet packages may have various different design requirements for otherwise similar chiplet designs. For instance, in the preceding example, a first version of the chiplet may implement an HPC interface for the HPC CPU while a second version of the chiplet may implement a standard interface. As another example, a first version of the chiplet may operate at a higher power than a second version of the chiplet (e.g., the first version may have a higher clock-speed, a higher number of active cores, etc. . . . ). In this example, the first version which might require additional package power supply pins over the second version. However, changing aspects of a chiplet design to meet the requirements of a particular package deployment may be challenging. For instance, modifying a chiplet design may spur additional testing or may require completely re-testing the new chiplet, which may add cost, incur production delays, and the like. As another example, it might not be cost-effective to modify a chiplet for a package that is likely to have fewer manufactured units compared to a more common package (e.g., a specialized testing SIP vs a laptop CPU).

Aspects of the disclosed technology may address challenges such as these by supporting chiplet designs having versions that may deployed in different package configurations. For example, a chiplet may include first semiconductor circuitry to implement a first communication interface, and second semiconductor circuitry to implement a second communication interface. A chiplet may include first contacts coupled to one of the first semiconductor circuitry or the second semiconductor circuitry corresponding to an active communication interface. In some such chiplets, the other of the first semiconductor circuitry or the second semiconductor circuitry may correspond to an inactive communication interface. In some implementations, the chiplet may include power-gating circuitry that prevents power from reaching the second interface in the first version and vice versa in the second version. In some implementations, different chiplet versions may differ in their metal interface layers (e.g., the back end of the line (BEOL) layers) while sharing design of other layers (e.g., the front/middle end of the line (FEOL/MEOL) layers).

Further aspects of the disclosed technology may address challenges such as these by providing a method of controlling power to a chiplet. For example, a method may include detecting a configuration of a chiplet package. The method may further include determining an inactive communication interface of a plurality of communication interfaces. For example, the plurality of communication interfaces may include an active communication interface connected to first contacts of a first chiplet. The method may further include power gating first semiconductor circuitry corresponding to the inactive communication interface, and operating second semiconductor circuitry corresponding to the active communication interface.

Still further aspects of the disclosed technology may provide a computer-readable medium storing computer-readable code for the fabrication of a device as described above and/or a device to function as described above.

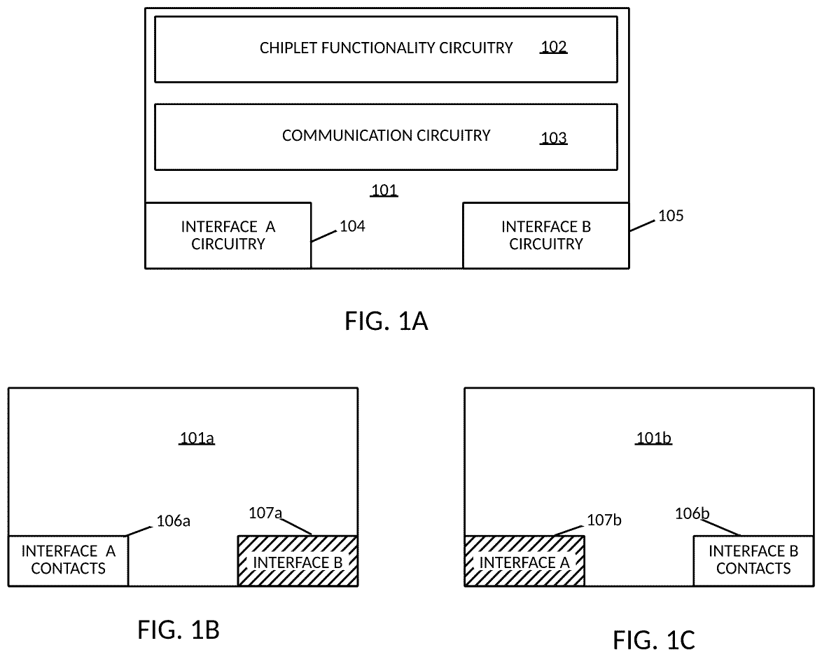

FIGS. 1A-1C illustrate example chiplets, in accordance with an implementation. In particular, FIG. 1A illustrates an example chiplet 101 including a plurality of semiconductor interface circuits 104, 105, FIG. 1B illustrates a first version 101a of chiplet 101 having an active first interface, and FIG. 1C illustrates a second version 101b of chiplet 101 having an active second interface.

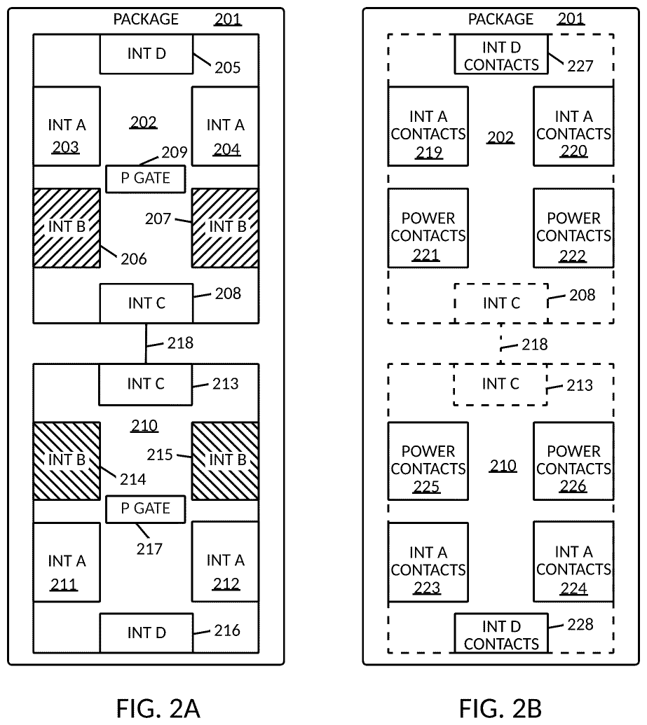

In some implementations, chiplet 101 may be disposed within a chiplet package. In various implementations, a package may comprise any package comprising one or more chiplets (“advanced package”), such as, for example, a multi-chip module, a stacked IC package (“3D IC”), chiplets coupled to a interposer (“2.5D IC”), wafer-level fan-out package, quilted chiplet package, and/or other packaged IC. In some implementations, a package may comprise a plurality of chiplets 101 (see, e.g., FIGS. 2-4). Accordingly, a package may comprise any multi-chip device, such as, for example, an accelerator, micro controller, central processing unit (CPU), graphics processing unit (GPU), memory module, storage device, and/or other computing system component.

In some implementations, chiplet 101 may may comprise chiplet functionality circuitry 102. For example, functionality circuitry 102 may comprise digital and/or analog circuitry, such as ASIC circuitry, memory circuitry and general executorial circuitry to store and execute firmware and/or other stored logic, FPGA or other programmable logic circuitry, other combinatorial digital/analog circuitry, and/or combinations thereof. For instance, functionality circuitry 102 may comprise a plurality of central processing units, graphics processing units, machine learning units, vision processing units, digital signal processors, network routing/bridging circuitry, ternary or standard content-addressable-memory (CAM/TCAM), cache circuitry, cache coherence/directory circuitry, combinations thereof, and/or the like.

In some implementations, chiplet 101 may comprise communication circuitry 103, which may include circuitry to facilitate communications between functionality circuitry 102 and chiplet-external devices (e.g. other co-packaged chiplets 101 and/or devices external to a package). In some implementations, communication circuitry 103 may comprise circuitry to perform various abstraction, translation, and/or like operations. For example, communication circuitry 103 may comprise memory controller circuitry, such as virtual-to-physical address translation circuitry, cache circuitry, interrupt control circuitry, arbitration circuity, and/or the like.

In various implementations, communication circuitry 103 may comprise circuity to format communications for an active interface. For instance, a chiplet implementing a remote memory access protocol might include a Remote Direct Memory over Converged Ethernet (RoCE) interface 104 and an Infiniband interface 105. In this example, communication circuitry 103 may comprise circuitry to translate general remote memory access requests from functionality circuitry 102 to requests formatted for either the RoCE or Infiniband protocols according to an active interface. In some implementations, communication circuitry 103 may comprise circuitry to detect an active interface. For example, as discussed below, an inactive interface may be de-powered by power gating circuitry. In this example, communication circuitry 103 may comprise circuitry to detect a powered interconnect to identify the active interface. As another example, communication circuitry 103 may comprise circuitry to determine an active interface via negotiating/probing interfaces 104, 105, such as during a power-on operation.

In some implementations, chiplet 101 may include semiconductor interface circuitry 104, 105 to implement a corresponding plurality of communication interfaces. For example, interface circuitry 104, 105 may comprise communication interface controller circuitry. In some implementations, interface circuitry 104, 105 may comprise circuitry to implement corresponding communication protocols.

In some implementations, interface circuitry 104, 105 may comprise transaction layer circuitry to generate transactions such as requests and responses based on signals received from communication circuitry 103, such as data reads and writes, addressed transaction requests (e.g., a request to perform a bitwise operation on addressed rows of memory in an in-memory computing implementation), coherency protocol requests, interrupts, discovery/configuration transactions, and/or the like. As an example, in response to a request to read a memory address received from communication circuitry 103, transaction layer circuitry 104, 105 may generate a corresponding protocol request, such as encapsulating the address in a packet according to the corresponding interface protocol.

In some implementations, interface circuitry 104, 105 may include data link layer circuitry to control receipt and delivery of frames (e.g., protocol data units). For instance, interface circuitry 104, 105 may comprise circuitry to perform error correction and/or detection, retransmission requests, flow control, link arbitration, media access control, and/or the like.

In some implementations, interface circuitry 104, 105 may include physical layer (PHY) circuitry to implement transmission and reception of signals on a corresponding interconnect, such as for example, bit-level communications over the physical link (e.g., the transmission of transactions as a stream of bit), line coding, PHY-level error correction, transmission frequencies, and/or the like. For example, interface circuitry 104, 105 may convert digital voltage-level signals to corresponding physical signals, such as electrical signals, optical signals, etc... For instance, interface circuitry 104, 105 may translate signals between a package-external power domain and a package-internal/chiplet power domain.

In various implementations, protocol-related function circuitry may be divided between interface circuitry 104 and communication circuitry 103 in any suitable manner. For example, a communication protocol implemented by chiplet 101 may have alternative physical layers (e.g., an optical physical layer and an electric physical layer or differently sized physical links). In this example, interface circuitry 104, 105 may comprise PHY circuitry while communication circuitry 103 may comprise circuitry to implement other aspects of the communication protocol. As another example, interface circuitry 104, 105 may be circuitry to implement different memory interconnects, such as DDR-type (e.g., DDR5, DDR6, DDRt, etc. . . . ) interface circuitry 104 and Compute Express Link (CXL) interface 105. As another example, interface circuitry 104 may comprise circuitry for a package-external interconnect, such as a DDR-type interconnect, and interface circuitry 104 may comprise circuitry for a chiplet-to-chiplet interconnect, such as a Universal Chiplet Interconnect express (UCIe)—type chiplet. In these examples, communication circuitry 103 may comprise memory controller circuitry to perform common operations independent of a specific interface, such as memory request arbitration, caching, virtual to physical address translation, and/or the like.

In some implementations, one of interfaces 104, 105 may be active and the other of the interfaces 105, 103 may be inactive. For example, FIG. 1B illustrates an example chiplet version 101a with an active interface 104 and FIG. 1C illustrates an example chiplet version 101b with an active interface 105.

In some implementations, a chiplet 101a, b may comprise contacts 106a, b coupled to an active interface 104, 105. For instance, FIG. 1B illustrates an example chiplet 101a having an active interface 104, including contacts 106a coupled to interface circuitry 104. Similarly, FIG. 1C illustrates an example chiplet 101b having an active interface 105, including contacts 106b coupled to interface circuitry 105. In some cases, chiplet 101a b may lack contacts for its inactive interface 107a b. In some implementations, chiplet 101a and chiplet 101b may differ in one or more of their BEOL layers (e.g., metal layers) and otherwise share circuit layer designs (e.g., MEOL, FEOL and any common BEOL layers). For example, chiplet 101a may include BEOL layers having metal traces connecting contacts 106a to interface 104, while chiplet 101b may include BEOL layers having metal traces connecting contacts 106b to interface 105.

In some implementations, chiplets 101a, 101b may have other differences in their floor plans. For instance, in some cases chiplet 101a, 101b may lack contacts for their inactive interfaces 107a, 107b. For instance, active interface contacts 106a, 106b may occupy area that would otherwise by used for contacts for inactive interface 107a, 107b. In some cases, a package-external interconnect may have a larger contact area and/or larger contacts compared to a package-internal interconnect. For example, package-external PCB-traversing interconnects may have higher power/signal integrity requirements compared to package internal die-to-die interconnects. In some implementations, die regions corresponding to an inactive interface 107a, 107b may differ between versions 101a, 101b.

FIGS. 2A, 2B illustrate an example chiplet package 201 comprising a plurality of chiplets 202, 210, in accordance with an implementation, where FIG. 2A illustrates chiplet circuitry and FIG. 2B illustrates an example of package-external contacts. For example, chiplets 202, 210 may comprise implementations of a chiplet 101 of FIGS. 1A-1C. In some implementations, chiplets 202, 210 may be instances of a common chiplet design, which may be rotated and/or translated with respect to each other. In further implementations, chiplets 202, 210 may have different designs, in at least some respects. However, for sake of explanation, implementations of FIGS. 2A, 2B will be described with respect to chiplets 202, 210 sharing a design.

In some implementations, chiplets 202, 210 may comprise circuitry to implement a plurality of interfaces. For example, chiplet 202, 210 may comprise circuitry 203, 204; 211, 212 to implement a interface type and circuitry 206, 207; 214, 215 to implement a second interface type. In some implementations, circuitry 203, 204; 211, 212 may comprise circuitry to implement multiple instances of a communication interconnect, such as, for example, multiple channels, links, lanes, and/or the like. As an example, circuitry 203, 204 may comprise interface circuitry for separate DDR channels connected to a memory controller to implement a multi-channel memory architecture, such as discussed with respect to communication circuitry 103 of FIG. 1A. As another example, interface circuitry 206, 207; 214, 215 may comprise interfaces for a chiplet-to-chiplet interconnect, such as a UCIe interconnect.

In various implementations, a chiplet 202, 210 may comprise additional interfaces 205, 216. For instance, chiplets 202, 210 may comprise interfaces 205, 216 that are operational in any version of the chiplet. For example, chiplets 202, 210 may comprise an external interface 205, 216 and a chiplet-to-chiplet interface 208, 213 located at opposite sides of their respective dies. For instance, external interface 205, 216 may be a peripheral interconnect interface, such as a Peripheral Component Interconnect Express (PCIe) interface. Accordingly, as illustrated, chiplet 210 may be rotated by 180° with respect to chiplet 202 where chiplet-to-chiplet interfaces 208, 213 are proximal to each other and connected by a chiplet-to-chiplet interconnect (e.g., a UCIe interconnect). In this arrangement, external interfaces 205, 216 may be proximal to opposing sides of package 201 and may comprise interface contacts 227, 228 in corresponding locations.

In some implementations, chiplets 202, 210 may comprise a plurality of inactive interfaces 206, 207; 214, 215. In some cases, inactive interfaces 206, 207; 214, 215 may be of the same type. For example, as illustrated, inactive interfaces 206, 207; 214, 215 are on opposite sides of chiplet dies 202, 210. In some implementations, inactive interfaces may be of different types. For instance, interfaces 203, 206 on a particular side of chiplet 202 may be inactive. For example, this may support chiplet versions that may be placed in any location within a package 201 (e.g., an “east” version might have interfaces 203, 206, 214, 211 inactive and a “west” version might have interfaces 204, 207, 215, 212 inactive).

In some implementations, a chiplet 202, 210 may comprise power gating circuitry 209, 217 to identify an inactive interface and power gate the corresponding inactive interface circuitry. For example, power gating the inactive interface may reduce and/or avoid power distribution by inactive interface circuitry. In some implementations, power gating circuitry 209, 217 may power gate inactive interfaces 206, 207; 215, 214 during each boot event. In other implementations, power gating circuitry 209, 217 may retain its identification over power cycles.

In various implementations, power gating circuitry 209, 217 may identify an inactive interface 206, 207; 214, 215 in any suitable manner. For example, power gating circuitry 209, 217 may detect a presence of contacts 219, 220; 225, 226 corresponding to an active interface 203, 204 and identify remaining interfaces 206, 207; 214, 215 as inactive. As another example, power gating circuitry 209, 217 may identify inactive interfaces 206, 207; 214, 215 based on a detected a location of its chiplets 209, 217 within package 201. For example, power gating circuitry 209, 217 may identify inactive interfaces based on a topological location of its chiplet 209, 217 on a chiplet-to-chiplet network. For instance, in a package comprising chiplets organized in a rectangular mesh network, a corner boundary chiplet might comprise two active links, a edge boundary chiplet might comprise three active links, and an intermediate/central chiplet might comprise four active links. In this example, power gating circuitry 209 may identify inactive interfaces 206, 207; 214, 215 based on link count, based on which links are active, or other link condition.

As a further example, chiplets 202, 210 may comprise chiplet identifiers, which may be set based, at least in part, on a chiplet version. In this example, power gating circuitry 209 may identify inactive interfaces based on this chiplet identifier (e.g., based on a derived chiplet version identifier). For instance, package 201 may comprise a bus that is operable prior to completing a boot process (e.g., an I2/3C bus, general-purpose I/O (GPIO) bus, etc. . . . ). In this example, chiplets 202,210 may use the bus to poll the identifiers of other chiplets 210, 202 within package 201. As another example, power gating circuitry 209, 217 may identify inactive interfaces 206, 207; 214, 215 based on a total chiplet count within package 201. For instance, power gating circuitry 209, 217 may identify a chiplet version based on a chiplet count threshold and/or other condition.

In some implementations, a package 201 may comprise contacts for package-external interfaces. For example, example package 201 of FIG. 2B may include contacts 219, 220; 223, 224 for active interfaces 203, 204; 211, 212. Package external contacts may be implemented in various manners according to chiplet package type. For instance, a package 201 might comprise a semiconductor interposer to which chiplets 202, 210 are coupled and contacts may be disposed on the interposer. In this example, the interposer may comprise metal traces, such as through-silicon vias and/or metal routing layers connecting contacts 219, 220; 223, 224 to active interfaces 203, 204; 211, 212.

In some implementations, as discussed above, a chiplet version may include alternative structures in regions underneath inactive interfaces 206, 207; 214, 215. For instance, as discussed above, chiplet versions may differ in their BEOL designs (e.g., metal layers) with alternative structures at least partially beneath inactive interfaces. As an example, chiplet 202, 210 may comprise power contacts 221, 222; 223, 224 under corresponding inactive interface circuitry 206, 207; 214, 215. For instance, in an implementation with an active package-external interface, additional power contacts 221, 222; 223, 224 may accommodate relatively higher powers/voltages of an external interface compared to an internal interface. As another example, a chiplet version having an active chiplet-to-chiplet interconnect may have power contacts under inactive external interconnect circuitry. For instance, this chiplet version may be instantiated in implementations having a relatively greater number of chiplets and power contacts may support relatively larger power requirements of a larger number of chiplets.

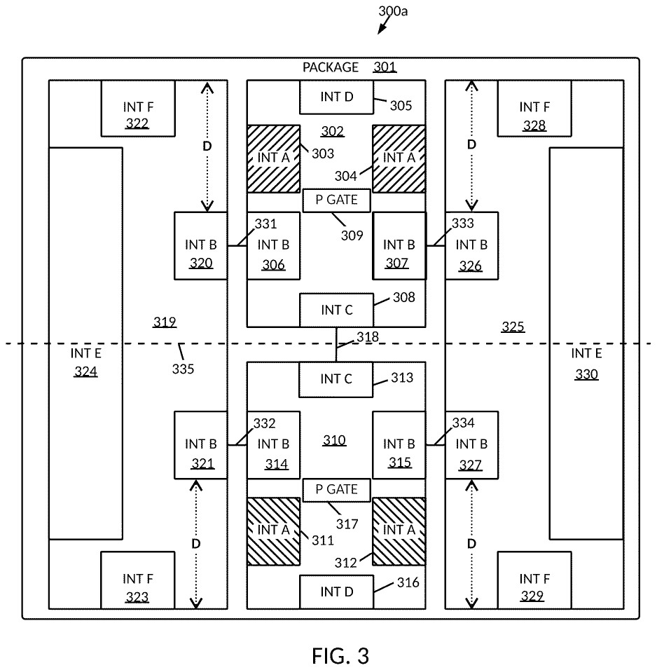

FIG. 3 illustrates an example device 300 including a package 301 comprising a plurality of chiplets 302, 310, 319, 325, in accordance with an implementation. Chiplets 302, 310 may, for example, comprise implementations of a chiplet 101 of FIG. 1. For instance, chiplets 302, 310 may comprise alternative versions of chiplets 202, 210. As example implementation, chiplets 202, 210 may comprise instances of a chiplet 101a while chiplets 302, 310 may comprise instances of a chiplet 101b.

In some implementations, chiplets 302, 310 may comprise various interface circuitry, such active interfaces 306, 307; 314, 315 and inactive interfaces 303, 304; 311, 312. For example, interfaces 306, 307; 314, 315 may comprise chiplet-to-chiplet interfaces and inactive interfaces 303, 304; 311, 312 may comprise package-external interfaces. Of course, in further implementations, both active and inactive interfaces may be external or both may be chiplet-to-chiplet. In further implementations, chiplets 302, 310 may comprise other interfaces, such as, for example, interfaces 305, 308, 313, 316. For example, interfaces 305, 316 may be implemented as described with respect to interfaces 205, 216 of FIG. 2 and interfaces 308, 313 may be implemented as described with respect to interfaces 208, 213.

In some implementations, inactive interfaces 303, 304; 311, 312 may be power gated during device operation. For instance, chiplets 302, 310 may comprise power gating circuitry 309, 317. In some implementations, power gating circuitry 309, 317 may identify inactive interfaces 303, 304; 311, 312, such as during a boot event. For instance, power gating circuitry 309, 317 may be as discussed with respect to power gating circuitry 209, 217 of FIG. 2. In some implementations, power gating circuitry 309, 317 may be instances of power gating circuitry 209, 217 comprise implementations of power gating circuitry 209, 217. Power gating circuitry 309, 317 may detect inactive interfaces 303, 304; 311, 312 under complementary conditions compared to detecting inactive interfaces 206, 207; 214, 215. As an example, power gating circuitry 209/309, 217/317 may identify inactive interfaces based on a threshold device count of package 201/301.

In various implementations, package 301 may comprise any combination of different types of chiplets, including chiplets lacking inactive interfaces as discussed herein. As an example, FIG. 3 illustrates a package 301 comprising a plurality of chiplets 319, 325 (“wing chiplets 319, 325”) located at either side of chiplets 302, 310 (“center chiplets 302, 310”). In some implementations, wing chiplets 319, 325 may comprise interface circuitry 322, 323, 324 for one or more external communication interconnects, such as an Advanced Microcontroller Bus Architecture (AMBA) interconnect (including, e.g., AXI, APB), CXL interconnect, DDR interconnect, PCIe interconnect, and/or the like. As a particular example, interfaces 322, 323, 328, 329 comprise interfaces for a coherent memory-semantic interconnect and interfaces 324, 330 may comprise interfaces for memory interconnects. For instance, device 300 may provide a cache-coherent bridge to a memory system For example, device 300 may connect devices connected to interfaces 322, 323, 328, 329 to memory devices connected to interfaces 324, 330 in a coherent manner.

In some cases, wing chiplets 319, 325 may be connected to each of center chiplets 302, 310 via chiplet-to-chiplet interconnects 331, 332, 333, 334. For example, wing chiplets 319, 325 may comprise interface circuitry and contacts 320, 321, 326, 327 of a chiplet-to-chiplet interconnect, such as, for example, a UCIe, UCIe-advanced (UCIe-a), Bunch of Wires (BoW), and/or like interconnect. For example, wing chiplet 319 and center chiplet 302 may be connected 331 via interface circuitry 320, 306; wing chiplet 319 and center chiplet 310 may be connected 332 via interface circuitry 321, 314; wing chiplet 325 may be connected 333 via interface circuitry 326, 407; and wing chiplet 325 may be connected 334 via interface circuitry 327, 315. In some implementations, interconnects 331, 332, 333, 334 may support the same die-to-die interconnect protocol and/or parameters as interconnect 318. In other implementations, interconnects 331, 332, 333, 334 may support different die-to-die interconnect protocols and/or parameters as interconnect 318. For instance, in the example of a cache-coherent memory bridge 300, traffic between wing chiplets 319, 325 (e.g., traffic between interface 328 and interface 323, between interface 322 and interface 330, etc. . . . ) may traverse one of the chiplets 302, 310. In this and other implementations, interconnects 331, 332, 333, 334 may be higher speed and/or bandwidth than interface 318.

In some implementations, wing chiplets 319, 325 may share aspects of their design and/or floorplan/layout. For instance, wing chiplets 319, 325 may be instances of a common design with interfaces arranged so that instances may be located on either side of chiplets 302, 310. In some implementations, interfaces 320, 321, 326, 327 may be located in a symmetric manner with respect to a wing chiplet midline 335. For instance, interfaces 320, 321, 326, 327 may be located a common distance D from the edges distal from midline 335. Additionally, in some implementations, interfaces 320, 326 and 321, 327 may have reflected layouts (e.g., reflected over midline 335). Accordingly, chiplets 325 and 319 may have layouts that are rotated by 180° with respect to each other. As an example, package 301 may comprise a first pair of instances 302, 310 of a first chiplet design and a second pair of instances 319, 325.

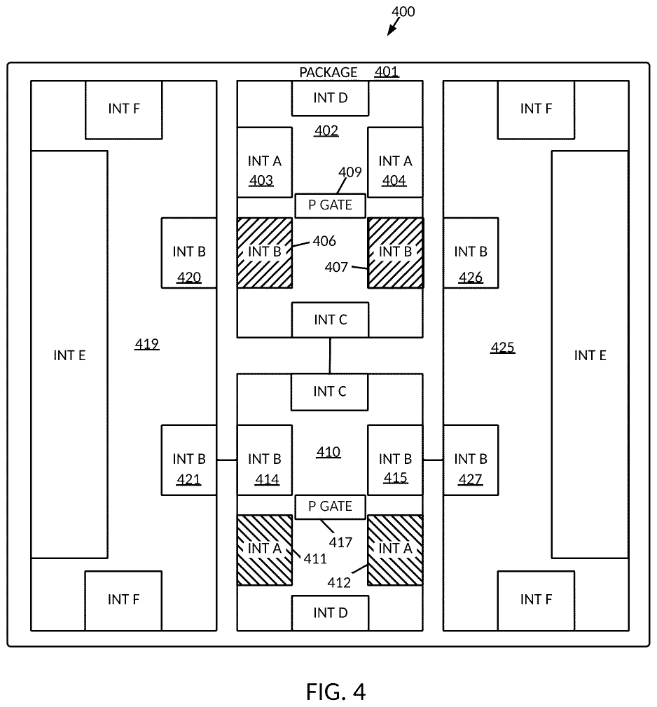

FIG. 4 illustrates an example device 400 comprising instances of chiplets 402, 410 as different versions of a common chiplet design, in accordance with an implementation. As discussed herein, a package may comprise different versions of a common chiplet design. As an illustration of these aspects, FIG. 4 illustrates a device 400 comprising an alternative version of device 300 of FIG. 3. For example, chiplets 402 may comprise an alternative version of chiplet 302 (e.g., an implementation of chiplet 202 of FIG. 2) and chiplet 410 may be as described with respect to chiplet 310. Continuing the example, chiplets 419, 425 may be implemented as discussed with respect to chiplets 319, 325.

In some implementations, chiplet-to-chiplet interfaces 406, 407 may be inactive and package-external interfaces 403, 404 may be active. In some implementations, other co-packaged chiplets 419, 425 may have different connectivity based, at least in part, on versions of chiplets 402, 410. For example, compared to interfaces 320, 326, chiplet-to-chiplet interfaces 420, 426 may lack a connection to interfaces 406, 407. Additionally, package 401 may have different external contacts compared to package 301. For instance, package 401 may comprise contacts for interface 403, 404.

In some implementations, power gating circuitry 409, 417 may determine the inactive interface based on conditions other than co-packaged device count. For example, power gating circuitry 409, 417 may probe connectivity of interfaces 403, 404, 414, 415 and power gate based on the results. In some implementations, power gating circuitry 409, 417 may power gate based on presence or absence of chiplet-to-chiplet connectivity. For instance, power gating circuitry 409 may power gate interfaces 406, 40 based on a lack of connectivity to interfaces 420, 426. As another example, power gating circuitry 410 may power gate package-external interfaces 411, 412 based on connectivity to interfaces 421, 427.

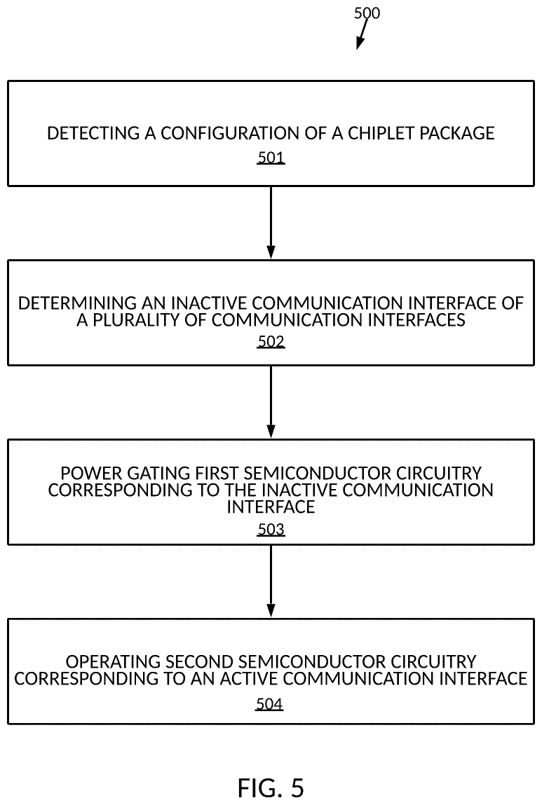

FIG. 5 illustrates a method 500 of operation, such as of devices implemented as described with respect to FIGS. 1-4. For example, method 500 may be performed by chiplet power gating circuitry as an aspect of powering on a device. As another example, method 500 may be performed by other circuitry, such as a controller chiplet connected to the chiplet to be power gated. In further implementations, method 500 may be performed independently by a plurality of chiplets within a package. For example with respect to FIG. 2, method 500 may be performed by power gating circuitry 209 and power gating circuitry 217 during a device power on operation.

In some implementations, method 500 may include operation 501, which includes detecting a configuration of a chiplet package. For example, operation 501 may include detecting a number of chiplets in a package, detecting a chiplet internal network topology, detecting package contacts associated with interfaces, and/or the like. As another example, operation 501 may comprise detecting the configuration based on chiplet identifiers. For example, a chiplet may detect a configuration of a corresponding chiplet package based on the chiplet's identifier, identifier format, and/or the like. For instance, a chiplet may be connected to other co-packaged chiplets via a bus that is operable prior to completing a boot process (e.g., an I2/3C bus, general-purpose I/O (GPIO) bus, etc. . . . ). In this example, the chiplet may use the bus to poll the identifiers of the other chiplets within the package.

In some implementations, method 500 may include operation 502, which may include determining an inactive communication interface of a plurality of communication interfaces. In some implementations, the plurality of communication interfaces may include an active communication interface connected to contacts of a chiplet, such as discussed above with respect to FIGS. 1-4. For example, operation 502 may be performed based, at least in part, on the configuration detected in operation 501. For example, operation 502 may comprise mapping a detected configuration to an inactive interface, such as, for example, via a look-up table.

In some implementations, method 500 may include operation 503, which may include power gating first semiconductor circuitry corresponding to the inactive communication interface. In various implementations, operation 503 may comprise performing any technique for depowering semiconductor devices. For instance, operation 503 may comprise activating power-gating transistors to decouple cells of semiconductor devices associated with the inactive interface from a power rail. As another example, operation 503 may comprise decoupling a portion (e.g., a branch) of a chiplet power distribution network corresponding to the inactive circuit.

In some implementations, method 500 may include operation 504, which may include operating second semiconductor circuitry corresponding to the active communication interface. For example, operation 504 may comprise operating an interconnect via the active communication interface. For instance, operation 504 may comprise communicating via a chiplet-to-chiplet interconnect and/or a package-external interconnect, as described above. As another example, operation 504 may comprise conducting interconnect set-up procedures according to a corresponding interconnect protocol. In some implementations, operation 504 may further comprise powering the chiplet via power contacts disposed at least partially beneath the active interface, such as described with respect to FIG. 2B.

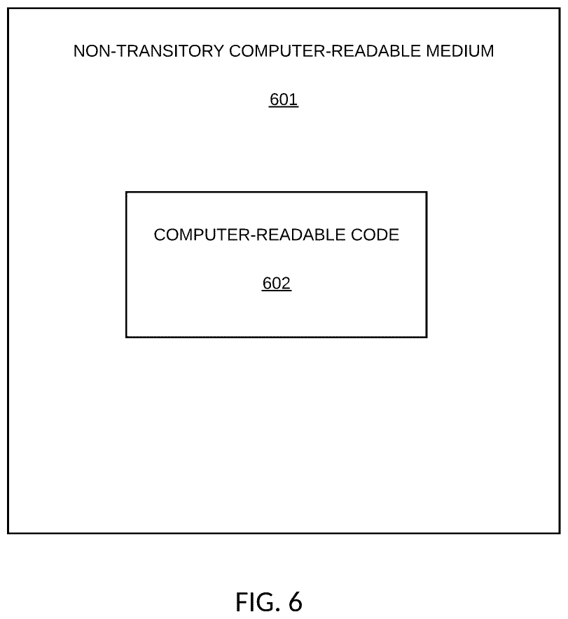

FIG. 6 llustrates an example of a non-transitory computer-readable medium 601 comprising computer-readable code 602. Concepts described herein may be embodied in computer-readable code 602 for fabrication of an apparatus that embodies the described concepts. For example, the computer-readable code 602 can be used at one or more stages of a semiconductor design and fabrication process, including an electronic design automation (EDA) stage, to fabricate an integrated circuit comprising the apparatus embodying the concepts. The above computer-readable code 602 may additionally or alternatively enable the definition, modeling, simulation, verification and/or testing of an apparatus embodying the concepts described herein.

For example, the computer-readable code 602 for fabrication of an apparatus embodying the concepts described herein can be embodied in code 602 defining a hardware description language (HDL) representation of the concepts. For example, the code 602 may define a register-transfer-level (RTL) abstraction of one or more logic circuits for defining an apparatus embodying the concepts. The code 602 may define an HDL representation of the one or more logic circuits embodying the apparatus in Verilog, SystemVerilog, Chisel, or VHDL (Very High Speed Integrated Circuit Hardware Description Language) as well as intermediate representations such as FIRRTL. Computer-readable code 602 may provide definitions embodying the concept using system-level modeling languages such as SystemC and SystemVerilog or other behavioral representations of the concepts that can be interpreted by a computer to enable simulation, functional and/or formal verification, and testing of the concepts.

Additionally or alternatively, the computer-readable code 602 may define a low level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code 602 a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code 602 may comprise a mix of code 602 representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code 602 defining instructions which are to be executed by the defined apparatus once fabricated.

Such computer-readable code 602 can be disposed in any known transitory computer-readable medium (such as wired or wireless transmission of code over a network) or non-transitory computer-readable medium 601 such as semiconductor, magnetic disk, or optical disc. An integrated circuit fabricated using the computer-readable code 602 may comprise components such as one or more of a central processing unit, graphics processing unit, neural processing unit, digital signal processor or other components that individually or collectively embody the concept.

Unless otherwise indicated, in the context of the present disclosure, the term “or” if used to associate a list, such as A, B, or C, is intended to mean A, B, and C, here used in the inclusive sense, as well as A, B, or C, here used in the exclusive sense. With this understanding, “and” is used in the inclusive sense and intended to mean A, B, and C; whereas “and/or” can be used in an abundance of caution to make clear that all of the foregoing meanings are intended, although such usage is not required. In addition, the term “one or more” and/or similar terms is used to describe any feature, structure, characteristic, and/or the like in the singular, “and/or” is also used to describe a plurality and/or some other combination of features, structures, characteristics, and/or the like. Furthermore, the terms “first,” “second” “third,” and the like are used to distinguish different aspects, such as different components, as one example, rather than supplying a numerical limit or suggesting a particular order, unless expressly indicated otherwise. Likewise, the term “based on” and/or similar terms are understood as not necessarily intending to convey an exhaustive list of factors, but to allow for existence of additional factors not necessarily expressly described.

Furthermore, it is intended, for a situation that relates to implementation of claimed subject matter and is subject to testing, measurement, and/or specification regarding degree, to be understood in the following manner. As an example, in a given situation, assume a value of a physical property is to be measured. If alternatively reasonable approaches to testing, measurement, and/or specification regarding degree, at least with respect to the property, continuing with the example, is reasonably likely to occur to one of ordinary skill, at least for implementation purposes, claimed subject matter is intended to cover those alternatively reasonable approaches unless otherwise expressly indicated.

In the preceding description, various aspects of claimed subject matter have been described. For purposes of explanation, specifics, such as amounts, systems and/or configurations, as examples, were set forth. In other instances, well-known features were omitted and/or simplified so as not to obscure claimed subject matter. While certain features have been illustrated and/or described herein, many modifications, substitutions, changes and/or equivalents will now occur to those skilled in the art. It is, therefore, to be understood that the appended claims are intended to cover all modifications and/or changes as fall within claimed subject matter.

Some configurations of the present techniques are described by the following numbered clauses:
Clause 1: A device, comprising:
   a first chiplet, comprising:
   first semiconductor circuitry to implement a first communication interface;
   second semiconductor circuitry to implement a second communication interface;
   first contacts coupled to one of the first semiconductor circuitry or the second semiconductor circuitry corresponding to an active communication interface, wherein
   the other of the first semiconductor circuitry or the second semiconductor circuitry corresponds to an inactive communication interface.
Clause 2: The device of clause 1, wherein the first chiplet further comprises power contacts disposed at least partially beneath the inactive semiconductor circuitry.
Clause 3: The device of any preceding clause, further comprising:
   power gating circuitry to identify the inactive communication interface and to power gate the corresponding first or second semiconductor circuitry responsive to the identification.
Clause 4: The device of any preceding clause, wherein the identification is based, at least in part, on a total number of chiplets co-packaged with the first chiplet.
Clause 5: The device of any preceding clause, wherein the first communication interface comprises a memory interface and the second communication interface comprises a chiplet-to-chiplet communication interface.
Clause 6: The device of any preceding clause, further comprising a second chiplet, the second chiplet comprising:
   third semiconductor circuitry to implement a third communication interface;
   fourth semiconductor circuitry to implement a fourth communication interface;
   second contacts coupled to an active one of the third semiconductor circuitry or the fourth semiconductor circuitry, wherein the other of the third semiconductor circuitry or the fourth semiconductor circuitry is inactive during chiplet operation.
Clause 7: The device of any preceding clause, wherein the first chiplet comprises a first layout, the second chiplet comprises a second layout, and the first layout is rotated by 180°with respect to the second layout.
Clause 8: The device of any preceding clause, further comprising a plurality of co-packaged respective chiplets, the plurality including the first chiplet, each respective chiplet comprising:
   respective first semiconductor circuitry to implement a respective first communication interface;
   respective second semiconductor circuitry to implement a respective second communication interface;
   respective contacts coupled to a respective active one of the respective first semiconductor circuitry or the respective second semiconductor circuitry, wherein the respective other of the respective first semiconductor circuitry or the respective second semiconductor circuitry is inactive during respective chiplet operation.
Clause 9: The device of any preceding clause, wherein the device further comprises:
   a chiplet-to-chiplet interconnect interconnecting the first chiplet and a co-packaged second chiplet.
Clause 10: The device of any preceding clause, wherein the first chiplet further comprises:
   a peripheral interface to interconnect the first chiplet and a device external to a package comprising the first chiplet.
Clause 11: A method, comprising:
   detecting a configuration of a chiplet package;
   determining an inactive communication interface of a plurality of communication interfaces, the plurality of communication interfaces including an active communication interface connected to first contacts of a first chiplet;
   power gating first semiconductor circuitry corresponding to the inactive communication interface; and
   operating second semiconductor circuitry corresponding to the active communication interface.
Clause 12: The method of clause 11, wherein the steps of detecting the configuration, determining the inactive communication interface, power gating the first semiconductor circuitry, and operating the second semiconductor circuitry are performed by the first chiplet.
Clause 13: The method of any of clauses 11-12, further comprising:
   the first chiplet determining the inactive communication interface based, at least in part, on a count of chiplets of the chiplet package.
Clause 14: The method of any of clauses 11-13, further comprising, by each respective chiplet of a plurality of chiplets co-packaged within the chiplet package:
   detecting the configuration of the chiplet package;
   determining a respective inactive communication interface of a respective plurality of communication interfaces, the respective plurality of communication interfaces including a respective active communication interface connected to first contacts of the respective chiplet;
   power gating respective first semiconductor circuitry corresponding to the respective inactive communication interface;
   operating respective second semiconductor circuitry corresponding to the respective

### Active Communication Interface.

Clause 15: The method of any of clauses 11-14, further comprising:
   powering the first chiplet, at least in part, via power contacts disposed at least partially beneath the first semiconductor circuitry.
Clause 16: The method of any of clauses 11-15, wherein the plurality of communication interfaces comprises a chiplet-to-chiplet communication interface and a package-external communication interface.
Clause 17: The method of any of clauses 11-16, wherein the package-external communication interface comprises a memory interconnect interface.
Clause 18: A non-transitory computer-readable medium storing computer-readable code for fabrication of an apparatus comprising:
   a first chiplet, comprising:
   first semiconductor circuitry to implement a first communication interface;
   second semiconductor circuitry to implement a second communication interface;
   first contacts coupled to one of the first semiconductor circuitry or the second semiconductor circuitry corresponding to an active communication interface, wherein the other of the first semiconductor circuitry or the second semiconductor circuitry corresponds to an inactive communication interface.
Clause 19: The non-transitory computer-readable medium of clauses 18, wherein the device further comprises:
   power gating circuitry to identify the inactive communication interface and to power gate the corresponding first or second semiconductor circuitry responsive to the identification.
Clause 20: The non-transitory computer-readable medium of clauses 18 or 19, wherein the device further comprises:
   a plurality of co-packaged respective chiplets, the plurality including the first chiplet, each respective chiplet comprising:
   respective first semiconductor circuitry to implement a respective first communication interface;
   respective second semiconductor circuitry to implement a respective second communication interface;
   respective contacts coupled to a respective active one of the respective first semiconductor circuitry or the respective second semiconductor circuitry, wherein the respective other of the respective first semiconductor circuitry or the respective second semiconductor circuitry is inactive during respective chiplet operation.
Clause 21: A non-transitory computer-readable medium storing computer-readable code for fabrication of a device of any of clauses 1-10.

Clause 22: A non-transitory computer-readable medium storing computer-readable code for performance of a method of any of clauses 11-17.

What is claimed is:

1. A device, comprising:
a first chiplet, comprising:
first semiconductor circuitry to implement a first communication interface;
second semiconductor circuitry to implement a second communication interface; and
first contacts coupled to one of the first semiconductor circuitry or the second semiconductor circuitry corresponding to an active communication interface, wherein the other of the first semiconductor circuitry or the second semiconductor circuitry corresponds to an inactive communication interface.

2. The device of claim 1, wherein the first chiplet further comprises power contacts disposed at least partially beneath the inactive semiconductor circuitry.

3. The device of claim 1, further comprising:
power gating circuitry to identify the inactive communication interface and to power gate the corresponding first or second semiconductor circuitry responsive to the identification.

4. The device of claim 3, wherein the identification is based, at least in part, on a total number of chiplets co-packaged with the first chiplet.

5. The device of claim 1, wherein the first communication interface comprises a memory interface and the second communication interface comprises a chiplet-to-chiplet communication interface.

6. The device of claim 1, further comprising a second chiplet, the second chiplet comprising:
third semiconductor circuitry to implement a third communication interface;
fourth semiconductor circuitry to implement a fourth communication interface; and
second contacts coupled to an active one of the third semiconductor circuitry or the fourth semiconductor circuitry, wherein the other of the third semiconductor circuitry or the fourth semiconductor circuitry is inactive during chiplet operation.

7. The device of claim 6, wherein the first chiplet comprises a first layout, the second chiplet comprises a second layout, and the first layout is rotated by 180°with respect to the second layout.

8. The device of claim 1, further comprising a plurality of co-packaged respective chiplets, the plurality including the first chiplet, each respective chiplet comprising:
respective first semiconductor circuitry to implement a respective first communication interface;
respective second semiconductor circuitry to implement a respective second communication interface; and
respective contacts coupled to a respective active one of the respective first semiconductor circuitry or the respective second semiconductor circuitry, wherein the respective other of the respective first semiconductor circuitry or the respective second semiconductor circuitry is inactive during respective chiplet operation.

9. The device of claim 1, wherein the device further comprises:
a chiplet-to-chiplet interconnect interconnecting the first chiplet and a co-packaged second chiplet.

10. The device of claim 1, wherein the first chiplet further comprises:
a peripheral interface to interconnect the first chiplet and a device external to a package comprising the first chiplet.

11. A method, comprising:
detecting a configuration of a chiplet package;
determining an inactive communication interface of a plurality of communication interfaces, the plurality of communication interfaces including an active communication interface connected to first contacts of a first chiplet;
power gating first semiconductor circuitry corresponding to the inactive communication interface; and
operating second semiconductor circuitry corresponding to the active communication interface.

12. The method of claim 11, wherein the steps of detecting the configuration, determining the inactive communication interface, power gating the first semiconductor circuitry, and operating the second semiconductor circuitry are performed by the first chiplet.

13. The method of claim 12, further comprising:
the first chiplet determining the inactive communication interface based, at least in part, on a count of chiplets of the chiplet package.

14. The method of claim 11, further comprising, by each respective chiplet of a plurality of chiplets co-packaged within the chiplet package:
detecting the configuration of the chiplet package;
determining a respective inactive communication interface of a respective plurality of communication interfaces, the respective plurality of communication interfaces including a respective active communication interface connected to first contacts of the respective chiplet;
power gating respective first semiconductor circuitry corresponding to the respective inactive communication interface; and
operating respective second semiconductor circuitry corresponding to the respective active communication interface.

15. The method of claim 11, further comprising:
powering the first chiplet, at least in part, via power contacts disposed at least partially beneath the first semiconductor circuitry.

16. The method of claim 11, wherein the plurality of communication interfaces comprises a chiplet-to-chiplet communication interface and a package-external communication interface.

17. The method of claim 16, wherein the package-external communication interface comprises a memory interconnect interface.

18. A non-transitory computer-readable medium storing computer-readable code for fabrication of an apparatus comprising:
a first chiplet, comprising:
first semiconductor circuitry to implement a first communication interface;
second semiconductor circuitry to implement a second communication interface; and
first contacts coupled to one of the first semiconductor circuitry or the second semiconductor circuitry corresponding to an active communication interface, wherein the other of the first semiconductor circuitry or the second semiconductor circuitry corresponds to an inactive communication interface.

19. The non-transitory computer-readable medium of claim 18, wherein the device further comprises:
power gating circuitry to identify the inactive communication interface and to power gate the corresponding first or second semiconductor circuitry responsive to the identification.

20. The non-transitory computer-readable medium of claim 18, wherein the device further comprises:
a plurality of co-packaged respective chiplets, the plurality including the first chiplet, each respective chiplet comprising:
respective first semiconductor circuitry to implement a respective first communication interface;
respective second semiconductor circuitry to implement a respective second communication interface;
respective contacts coupled to a respective active one of the respective first semiconductor circuitry or the respective second semiconductor circuitry, wherein the respective other of the respective first semiconductor circuitry or the respective second semiconductor circuitry is inactive during respective chiplet operation.
